(19) United States
(12) Patent Application Publication
(10) Pub. No.: US 2023/0309417 A1
(43) Pub. Date: Sep. 28, 2023

(54) RESONATOR WITH VAN DER WAALS MATERIAL

(71) Applicants: RAYTHEON BBN TECHNOLOGIES CORP., Cambridge, MA (US); COLUMBIA UNIVERSITY, New York, NY (US)

(72) Inventors: Kin Chung FONG, Concord, MA (US); Guilhem Jean Antoine RIBEILL, Bedford, MA (US); Martin GUSTAFSSON, Cambridge, MA (US); James Curtis HONE, New York, NY (US)

(21) Appl. No.: 18/161,019

(22) Filed: Jan. 27, 2023

Related U.S. Application Data
(60) Provisional application No. 63/323,028, filed on Mar. 23, 2022.

(51) Int. Cl. H01P 7/08; H10N 60/12; H10N 60/80; G06N 10/40; H10N 69/00

(52) U.S. Cl. CPC H10N 60/12; G06N 10/40; H01P 7/086; H10N 60/805; H10N 69/00

(57) ABSTRACT

A resonator constructed with one or more Van der Waals materials. In some embodiments, a system includes such a resonator. The resonator may include: a capacitor; and an inductor, the capacitor including: a first conductive layer; an insulating layer, on the first conductive layer; and a second conductive layer on the insulating layer, the first conductive layer being composed of one or more layers of a first van der Waals material, the insulating layer being composed of one or more layers of a second van der Waals material, and the second conductive layer being composed of one or more layers of a third van der Waals material.

### CROSS-REFERENCE TO RELATED APPLICATION(S)

The present application claims priority to and the benefit of U.S. Provisional Application No. 63/323,028, filed Mar. 23, 2022, entitled “Van der Waals materials for high-quality factor microwave resonator”, the entire content of which is incorporated herein by reference.

### FIELD

One or more aspects of embodiments according to the present disclosure relate to Van der Waals materials, and more particularly to a resonator constructed with one or more Van der Waals materials.

### BACKGROUND

In various applications, including quantum computing, a resonator with a high quality factor may be used. For example, a system including one or more quantum bits, or “qubits”, may be constructed with one or more such resonators.

It is with respect to this general technical environment that aspects of the present disclosure are related.

### SUMMARY

According to an embodiment of the present disclosure, there is provided a system, including: a resonator, including: a capacitor; and an inductor, the capacitor including: a first conductive layer; an insulating layer, on the first conductive layer; and a second conductive layer on the insulating layer, the first conductive layer being composed of one or more layers of a first van der Waals material, the insulating layer being composed of one or more layers of a second van der Waals material, and the second conductive layer being composed of one or more layers of a third van der Waals material.

In some embodiments, the capacitor further includes: an insulating lower layer, under the first conductive layer; and an insulating upper layer, on the second conductive layer, wherein: the insulating lower layer is composed of one or more layers of a first van der Waals material, and the insulating upper layer is composed of one or more layers of a first van der Waals material.

In some embodiments, the capacitor further includes: a first layer of graphene, between the first conductive layer and the insulating layer; and a second layer of graphene, between the insulating layer and the second conductive layer.

In some embodiments, the first conductive layer is a superconducting layer and the second conductive layer is a superconducting layer.

In some embodiments, the first van der Waals material is a material selected from the group consisting of NbSe₂, MoTe₂, WTe₂, TaS₂, BSCCO, graphene, and combinations thereof.

In some embodiments, the third van der Waals material is the same material as the first van der Waals material.

In some embodiments, the second van der Waals material is a material selected from the group consisting of BN, WSe₂, MoS₂, MoSe₂, WS₂, MoTe₂, PtS₂, PtSe₂, PtTe₂, HfS₂, HfSe₂, ReS₂, ReSe₂, SnS₃, SnSe₂, ZrS₂, ZrSe₂, silicene, germanene, black phosphorus, and combinations thereof.

In some embodiments, the inductor has an inductance that is primarily due to geometric inductance.

In some embodiments, the inductor has an inductance that is primarily due to kinetic inductance.

In some embodiments, the inductor has an inductance that is primarily due to a Josephson inductance.

In some embodiments, the Josephson inductance is an inductance of a Josephson junction, the Josephson junction including: a first conductive layer, contiguous with the first conductive layer of the capacitor; an insulating layer, contiguous with the insulating layer of the capacitor; and a second conductive layer, contiguous with the second conductive layer of the capacitor.

In some embodiments, the insulating layer of the Josephson junction is thinner than the insulating layer of the capacitor.

In some embodiments, the Josephson inductance is an inductance of a Josephson junction, the Josephson junction being formed between the first conductive layer and the second conductive layer.

In some embodiments, an overlap of a wavefunction of electrons of the first conductive layer with a wavefunction of electrons of the second conductive layer results in the formation of the Josephson junction.

In some embodiments, the system further includes: a first electrode, in contact with the first conductive layer, and a second electrode, in contact with the second conductive layer.

In some embodiments, the first electrode is composed of a superconducting material.

In some embodiments, the first electrode is composed of a material selected from the group consisting of aluminum, niobium, niobium nitride, niobium titanium nitride, titanium nitride, and molybdenum rhenium.

In some embodiments, the system further includes a qubit, wherein: the capacitor is a first capacitor, and the qubit is capacitively coupled to the first capacitor.

In some embodiments: the qubit includes a second capacitor; and the second capacitor includes: a first conductive layer; an insulating layer, on the first conductive layer; and a second conductive layer on the insulating layer.

In some embodiments, the qubit is capacitively coupled to the first capacitor as a result of an overlap between the first conductive layer of the second capacitor and the second conductive layer of the first capacitor.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Features, aspects, and embodiments are described in conjunction with the attached drawings, in which:

FIG. 1 is a schematic drawing of a qubit, according to an embodiment of the present disclosure;

FIG. 2 is a schematic drawing of a capacitor, according to an embodiment of the present disclosure;

FIG. 3A is a schematic diagram of a resonator, according to an embodiment of the present disclosure;

FIG. 3B is an equation describing a resonator, according to an embodiment of the present disclosure;

FIG. 3C is a schematic perspective view of a resonator, according to an embodiment of the present disclosure;

FIG. 3D is a schematic illustration of a resonator, according to an embodiment of the present disclosure;

FIG. 3E is a schematic illustration of a resonator, according to an embodiment of the present disclosure;

FIG. 3F is a schematic illustration of a resonator, according to an embodiment of the present disclosure;

FIG. 3G is a schematic illustration of an equivalent circuit of a resonator, according to an embodiment of the present disclosure;

FIG. 4A is a schematic illustration of a system including a resonator, according to an embodiment of the present disclosure;

FIG. 4B is a schematic illustration of a system including a resonator, according to an embodiment of the present disclosure;

FIG. 5 is a schematic diagram of a qubit, according to an embodiment of the present disclosure;

FIG. 6 is a schematic drawing of a capacitor, according to an embodiment of the present disclosure;

FIG. 7A is a photograph of a qubit circuit, according to an embodiment of the present disclosure; and

FIG. 7B is an enlarged view of a portion of FIG. 7A.

### DETAILED DESCRIPTION

The detailed description set forth below in connection with the appended drawings is intended as a description of exemplary embodiments of a resonator constructed with one or more Van der Waals materials provided in accordance with the present disclosure and is not intended to represent the only forms in which some embodiments may be constructed or utilized. The description sets forth the features of the present disclosure in connection with the illustrated embodiments. It is to be understood, however, that the same or equivalent functions and structures may be accomplished by different embodiments that are also intended to be encompassed within the scope of the disclosure. As denoted elsewhere herein, like element numbers are intended to indicate like elements or features.

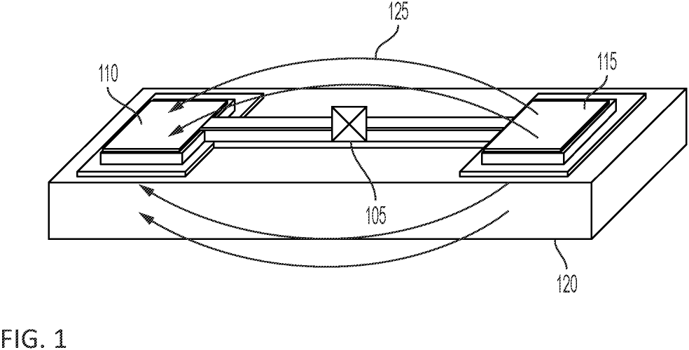

FIG. 1 shows a quantum bit, or “qubit”, in some embodiments. The quantum bit may be characterized by two quantum mechanical states, separated by an energy difference. A Josephson junction 105 is connected between a first metal (e.g., superconducting metal) pad 110 and a second metal (e.g., superconducting metal) pad 115. In operation, the first metal pad 110 and the second metal pad 115 form a capacitor connected in parallel with the Josephson junction 105. The structure may be fabricated on a substrate 120. Exemplary electric field lines 125, between a first charge on the first metal pad 110 and a second charge on the second metal pad 115, are shown. These field lines may cross (i) a substrate to air interface, (ii) a metal to air interface, and (iii) a substrate to metal interface, at one or more points. At these interfaces, impurities or other imperfections may give rise to two-level systems having respective energy differences similar to that of the qubit; these two-level systems may interact with the qubit, resulting in loss and a degradation in performance.

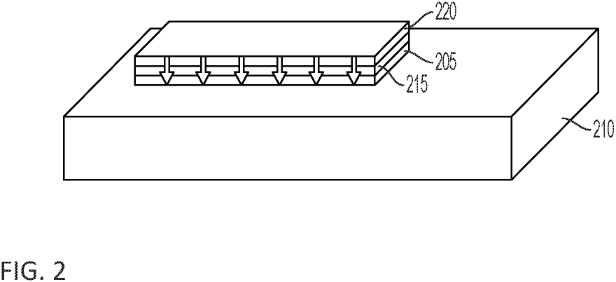

In some embodiments, a capacitor is instead formed as a stack of layers of van der Waals materials, as illustrated in FIG. 2. The capacitor includes a first conductive layer 205 on a substrate 210, an insulating layer 215, on the first conductive layer 205, and a second conductive layer 220 on the insulating layer 215. The first conductive layer 205 may be composed of one or more layers of a first van der Waals material, the insulating layer 215 may be composed of one or more layers of a second van der Waals material, and the second conductive layer 220 may be composed of one or more layers of a third van der Waals material. The third van der Waals material may be the same material as the first van der Waals material. Exemplary electric field lines 225 are shown. Except for fringing fields (not shown) each line of electric field extends directly from the second conductive layer 220 to the first conductive layer 205, passing through (i) a first interface between the second conductive layer 220 and the insulating layer 215 and (ii) a second interface between the first conductive layer 205 and the insulating layer 215. These interfaces may be significantly cleaner than the substrate to air interface, the metal to air interface, and the substrate to metal interface of the embodiment of FIG. 1. Although other interfaces (e.g., an air to substrate interface) are present in the embodiment of FIG. 2, the coupling of the capacitor to these interfaces may be relatively weak because only fringing fields may interact with these interfaces. Moreover, the capacitor of the embodiment of FIG. 2 may be significantly smaller (e.g., up to a factor of 1000 smaller) than the structure of FIG. 1. In some embodiments, the capacitor further includes an insulating lower layer (which may be composed of one or more layers of a van der Waals material), under the first conductive layer; and an insulating upper layer (which may be composed of one or more layers of a van der Waals material), on the second conductive layer. In some embodiments, the capacitor further includes a first layer of graphene, between the first conductive layer and the insulating layer, and a second layer of graphene, between the insulating layer and the second conductive layer.

The first conductive layer 205 and the second conductive layer 220 may be superconducting layers, e.g., at sufficiently low temperature, current density, and magnetic field, each of the first conductive layer 205 and the second conductive layer 220 may be in a superconducting state. As used herein, a material or structure may be said to be “superconducting” if, at sufficiently low temperature, current density, and magnetic field it will be in, or it will transition to, a superconducting state. As used herein, this term (“superconducting”) also applies to the structure or material when it is not in a superconducting state. As such, aluminum, or an aluminum electrode, may be referred to as “superconducting”, even when it is at room temperature (and not in a superconducting state). Each of (i) the first conductive layer 205, (ii) the insulating layer 215, and (iii) the second conductive layer 220 may be composed of a van der Waals material. For example, each of the first conductive layer 205 and the second conductive layer 220 may be composed of niobium selenide (NbSe₂), molybdenum telluride (MoTe₂), tungsten telluride (WTe₂), tantalum sulfide (TaS₂), bismuth strontium calcium copper oxide (BSCCO), combinations (e.g., alloys) of these materials, or one of various thicknesses and twist angles of graphene. The insulating layer 215 may be composed of boron nitride (BN), tungsten selenide (WSe₂), molybdenum sulfide (MoS₂), MoSe₂, WS₂, MoTe₂, PtS₂, PtSe₂, PtTe₂, HfS₂, HfSe₂, ReS₂, ReSe₂, SnS₃, SnSe₂, ZrS₂, ZrSe₂, silicene, germanene, or black phosphorus. In other embodiments, other suitable conducting (e.g., superconducting) or insulating materials may be used, respectively. In some embodiments, the insulating layer 215 includes fewer than 100 monolayers; the low thickness of this layer may result in a high capacitance per unit area of the capacitor. In some embodiments the insulating layer 215 includes fewer than 10 (e.g., as few as one or two) monolayers; the thickness may be selected to be the smallest thickness for which the tunneling effect is negligible or acceptably small.

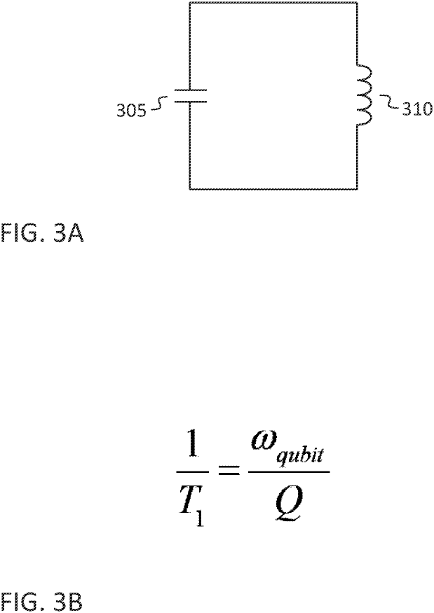

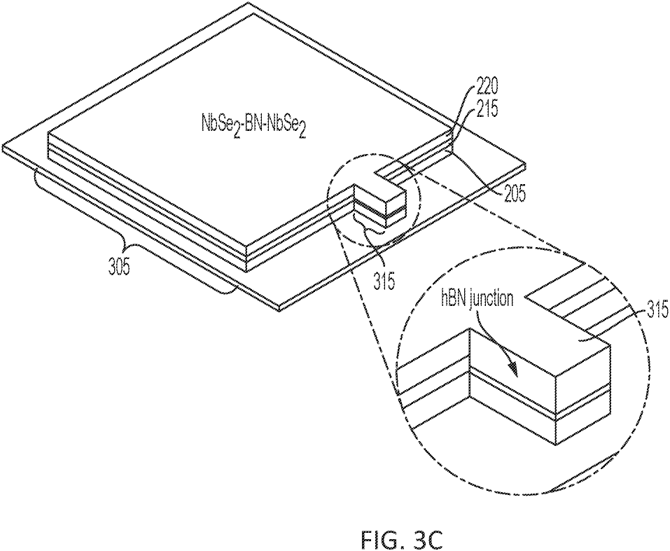

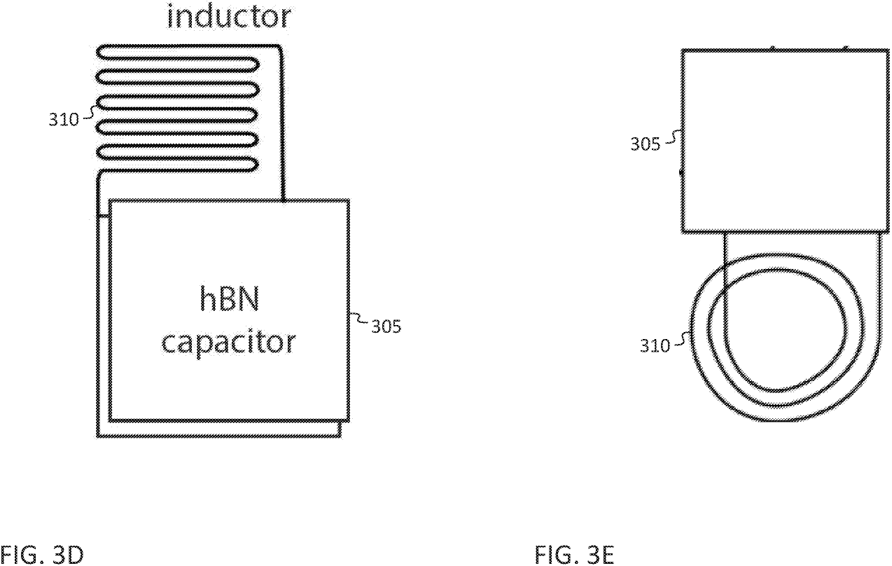

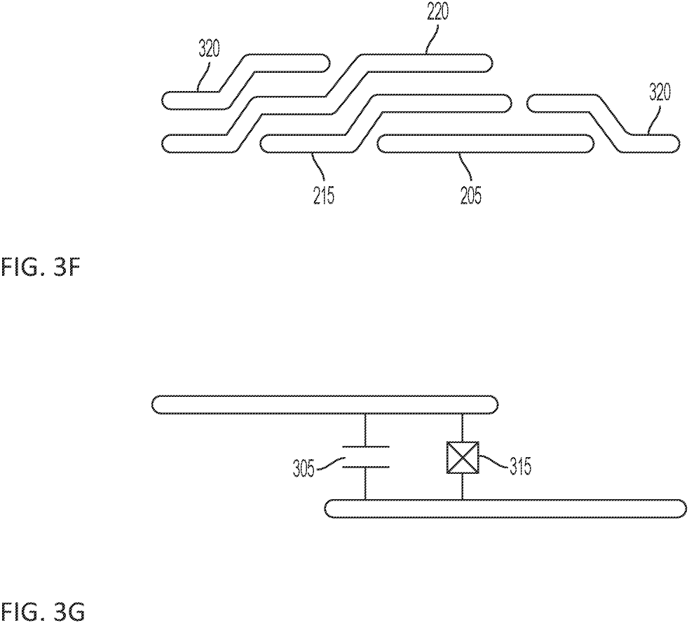

FIG. 3A is a schematic diagram of an inductor - capacitor (LC) resonator, including a capacitor 305 and an inductor 310, connected in parallel. FIG. 3B shows an equation relating the relaxation time T₁ of the resonator to the Q of the resonator and to the resonant frequency W_{qubit}. It may be seen that the higher the Q, the longer the relaxation time T₁. The Q for the capacitor or for the inductor may be defined as the reciprocal of the loss tangent.

The inductor may be implemented in various ways. For example, FIGS. 3C, 3F, and 3G (discussed in further detail below) illustrate embodiments in which the inductance is implemented as a Josephson inductance, and FIGS. 3D and 3E (discussed in further detail below) illustrate embodiments in which the inductance is due primarily to kinetic inductance and geometric inductance, respectively. FIG. 3C is a schematic perspective drawing of the structure of a resonator, in some embodiments. The resonator includes a capacitor 305 and a Josephson junction 315 connected in parallel with the capacitor 305. The Josephson junction 315 may operate as an inductor 310 having an inductance equal to the Josephson inductance of the Josephson junction 315. The structure may be constructed of three layers, a first conductive layer 205, an insulating layer 215, and a second conductive layer 220 as shown. Each of the first conductive layer 205, the insulating layer 215, and the second conductive layer 220 may be a Van der Waals material, and each of the first conductive layer 205 and the second conductive layer 220 may be superconducting. The insulating layer 215 may be thinner in the portion of the structure that forms the Josephson junction 315. As such, it may be the case that (i) in the portion of the structure that is the capacitor 305, the wavefunctions of electrons in the first conductive layer 205 do not overlap significantly with the wavefunctions of electrons in the second conductive layer 220, and that (ii) in the portion of the structure that is the Josephson junction 315, the wavefunctions of electrons in the first conductive layer 205 overlap significantly with the wavefunctions of electrons in the second conductive layer 220. The material combinations used for the first conductive layer 205, the insulating layer 215 and the second conductive layer 220 may be any of the combinations discussed above in the context of FIG. 2.

In some embodiments, the inductor may be constructed to exhibit an inductance that is primarily due to kinetic inductance or an inductance that is primarily due to geometric inductance. For example, FIG. 3D shows a resonator including a capacitor 305 and an inductor 310 that is constructed as a serpentine conductive trace (composed of a superconducting material) having an inductance that is primarily due to kinetic inductance. As another example, FIG. 3E shows a resonator including a capacitor 305 and an inductor 310 that is constructed as a spiral conductive trace (composed of a superconducting material) having an inductance that is primarily due to geometric inductance. In the embodiment of FIG. 3E, the inductor may be fabricated, for example, by fabricating the spiral (except for the conductive trace extending from the interior of the spiral to the exterior of the spiral) in one layer (e.g., using a photolithographic method), covering the spiral with an insulating layer, fabricating the conductive trace extending from the interior of the spiral to the exterior of the spiral (e.g., using a photolithographic method), so that it forms a bridge from the interior of the spiral to the exterior of the spiral, and making connections to the two ends of the conductive trace extending from the interior of the spiral to the exterior of the spiral using conductive vias extending through the insulating layer (vias which may be fabricated before the fabrication of the conductive trace extending from the interior of the spiral to the exterior of the spiral).

FIG. 3F is a schematic drawing of a merged-element resonator in which a single conductor-insulator-conductor sandwich (including a first conductive layer 205, an insulating layer 215, and a second conductive layer 220) operates as both a (parallel plate) capacitor and as an inductor. In the embodiment of FIG. 3F, the insulating layer 215 is selected to be sufficiently thin that a significant Josephson effect is present (e.g., sufficiently thin that an inductor is present as a result of overlapping of the wavefunctions of electrons in the first conductive layer 205 with the wavefunctions of electrons in the second conductive layer 220). This overlapping causes the structure of FIG. 3F to include both a capacitor and a Josephson junction 315, which operates as an inductor. Also shown in FIG. 3F are conductors 320 (which may be referred to as “electrodes”) that may be used to connect the merged-element resonator to other circuit elements. FIG. 3G is an equivalent circuit diagram of the structure of FIG. 3F.

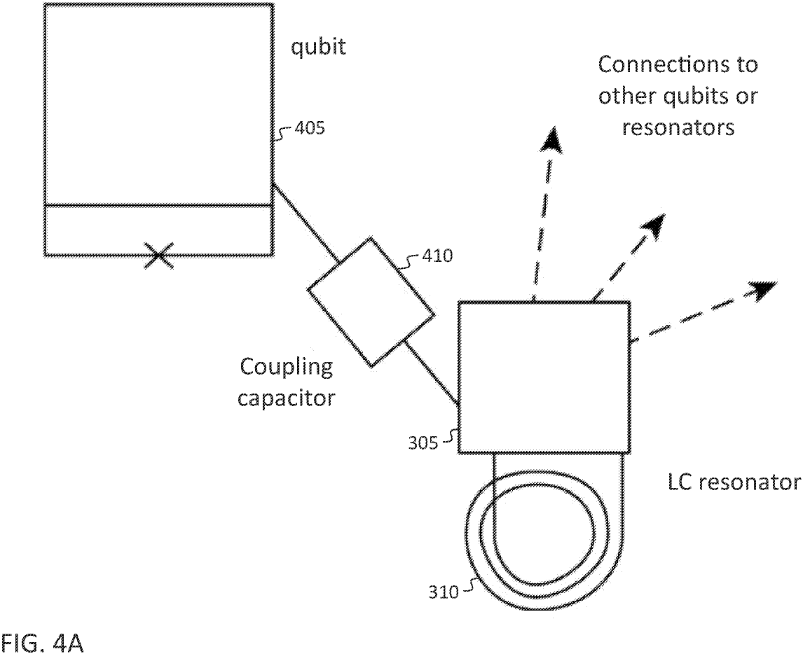

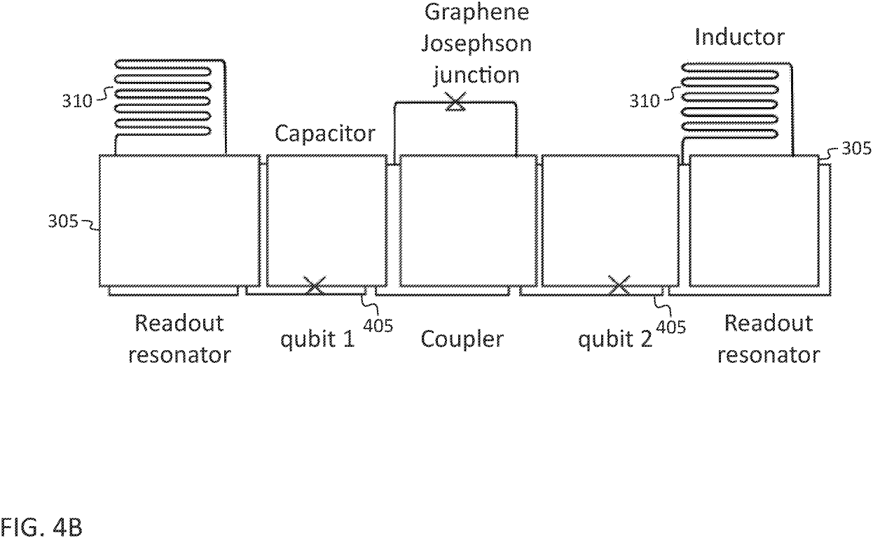

FIG. 4A is a schematic drawing of an LC resonator capacitively coupled, by a coupling capacitor 410, to a qubit 405. The LC resonator shown is that of the embodiment of FIG. 3E; in other embodiments the LC resonator of any one of FIGS. 3C, 3D, or 3F may be coupled to a qubit 405 in the same manner (using a coupling capacitor 410). Dashed arrows in FIG. 4A indicate that connections to other qubits and resonators may be made in the same manner, using additional coupling capacitors. FIG. 4B is a schematic drawing of a system including five elements: two qubits 405, two readout resonators, and a coupler. Each of the five elements includes a parallel plate capacitor; coupling between adjacent elements of the five elements is provided by constructing each upper conductive plate (e.g., each second conductive layer 220) to overlap a lower plate (e.g., a first conductive layer 205) of an adjacent capacitor.

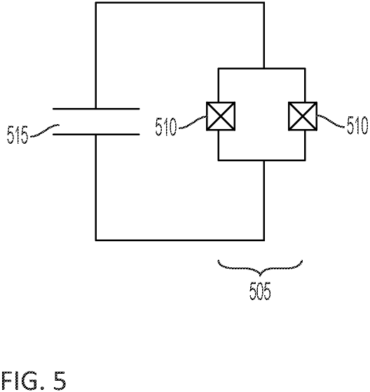

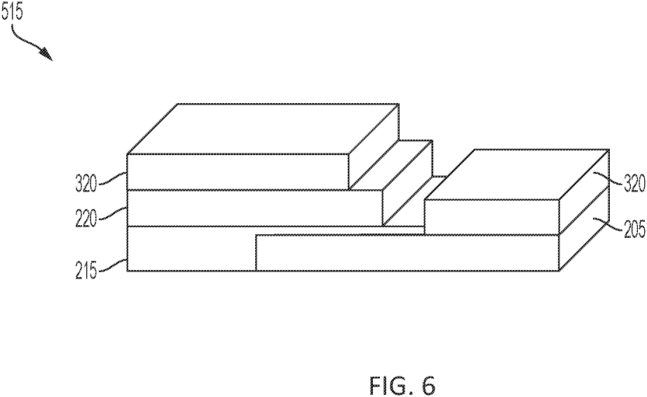

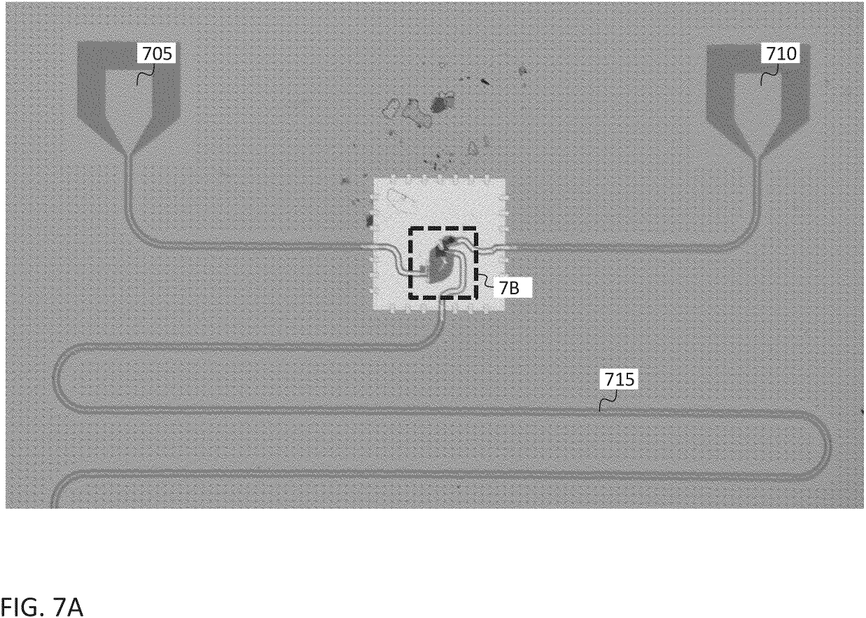

FIG. 5 shows a tunable frequency transmon qubit, which includes (i) a superconducting quantum interference device (SQUID) 505 including two Josephson junctions 510 connected in a loop, and (ii) a capacitor 515 (e.g., the capacitor of FIG. 3 or the capacitor of FIG. 6 (discussed in further detail below)), connected in parallel with the SQUID 505. In some embodiments, a fixed frequency transmon qubit (having, instead of the SQUID 505, a single Josephson junction 510, connected in parallel with the capacitor 515) may be constructed in an analogous manner.

FIG. 6 is a schematic drawing of a capacitor 515, in some embodiments. The capacitor 515 includes (like the capacitor of the embodiment of FIG. 3) a first conductive layer 205, an insulating layer 215, on the first conductive layer 205, and a second conductive layer 220 on the insulating layer 215. The capacitor further includes two electrodes 320 in contact with the first conductive layer 205 and the second conductive layer 220, respectively.

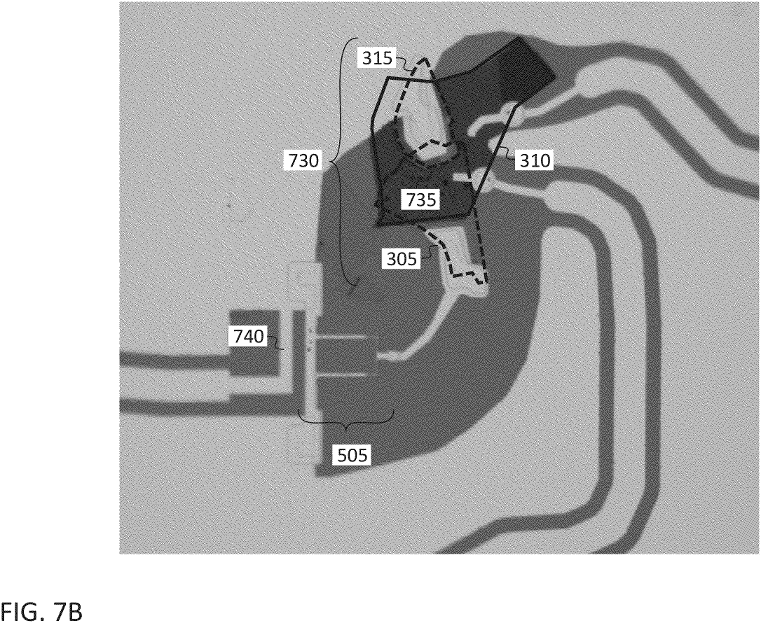

FIG. 7A is a photograph of a reduction to practice, in one embodiment, of a qubit including a capacitor according to embodiments described herein. FIG. 7B is an enlarged view of a portion (labeled “7B”) of FIG. 7A. The circuit may be fabricated on a silicon (e.g., float-zone silicon) substrate, or wafer. FIG. 7A shows three external connections to the qubit, which is illustrated in FIG. 7B. A first wire bond pad 705 is terminated to ground at a point adjacent to the qubit. A bias current supplied through the first wire bond pad 705 may be employed to produce a magnetic field at the qubit, to control the critical current of the SQUID loop of the qubit, and to control the frequency of the qubit. A second wire bond pad 710 may be capacitively coupled to the SQUID. Control pulses may be sent to the qubit via the second wire bond pad 710 to control the state of the qubit (e.g., to rotate the state of the qubit in the Bloch sphere). The third connection illustrated in FIG. 7A is a microwave resonator 715, which may be employed to read out the qubit. The microwave resonator 715 and the connections to the first wire bond pad 705 and to the second wire bond pad 710 may each be constructed as a coplanar microwave waveguide.

FIG. 7B shows, as mentioned above, an enlarged view of the qubit of FIG. 7A. The capacitor 730 includes a first conductive layer 205 (e.g., a layer of niobium diselenide), an insulating layer 215 (e.g., a layer of boron nitride (e.g., of hexagonal boron nitride)), and a second conductive layer 220 (e.g., a layer of niobium diselenide). The capacitance of the capacitor is largely determined by an area of overlap 735, within which each of the first conductive layer 205, the insulating layer 215, and the second conductive layer 220 is present. The capacitor is connected to a SQUID 505, the magnetic field in which may be controlled by adjusting the current flowing in a conductive segment 740 (which may be connected to the first wire bond pad 705 through a coplanar microwave waveguide).

The capacitor 730 of FIGS. 7A and 7B may be fabricated as follows. The first conductive layer 205 may be exfoliated from a niobium diselenide bulk crystal using a suitable adhesive exfoliating tool, and transferred to the bare silicon substrate. The insulating layer 215 may then be exfoliated from a boron nitride bulk crystal, and placed in a position partially overlapping the first conductive layer 205 (and leaving a portion of the first conductive layer 205 exposed), and the second conductive layer 220 may then be exfoliated from a niobium diselenide bulk crystal and placed on the substrate, such that a portion of the second conductive layer 220 overlaps the region in which the insulating layer 215 overlaps the first conductive layer 205. Electrodes (e.g., aluminum electrodes) may then be fabricated to contact the first conductive layer 205 (e.g., the exposed portion of the first conductive layer 205) and the second conductive layer 220.

The fabrication of the electrodes may include (i) forming a layer of resist (e.g., photoresist or e-beam resist) over the wafer, (ii) patterning the photoresist (e.g., using e-beam lithography) to remove the photoresist in areas in which metal (e.g., aluminum) is to be deposited, (iii) depositing a layer of metal (e.g., aluminum) over the wafer, and (iv) removing the photoresist and the portions of the metal layer that are on photoresist, using a lift-off process. The conductors forming the external connections (e.g., the first wire bond pad 705, the second wire bond pad 710, the coplanar waveguides connected to them, and the microwave resonator 715) may be formed at the same time. Because the shapes of the exfoliated layers may be unpredictable (e.g., they may vary from one exfoliation operation to another), the shape of the metal (e.g., aluminum) layer to be formed may be designed after the first conductive layer 205, the insulating layer 215, and the second conductive layer 220 have been placed on the substrate. The SQUID 505 may be fabricated before or after the capacitor.

As used herein, “a portion of” something means “at least some of” the thing, and as such may mean less than all of, or all of, the thing. As such, “a portion of” a thing includes the entire thing as a special case, i.e., the entire thing is an example of a portion of the thing. As used herein, the word “or” is inclusive, so that, for example, “A or B” means any one of (i) A, (ii) B, and (iii) A and B.

It will be understood that when a layer is referred to as being “between” two layers, it can be the only layer between the two layers, or one or more intervening layers may also be present. The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art.

As used herein, the term “major component” refers to a component that is present in a composition, polymer, or product in an amount greater than an amount of any other single component in the composition or product. In contrast, the term “primary component” refers to a component that makes up at least 50% by weight or more of the composition, polymer, or product. As used herein, the term “major portion”, when applied to a plurality of items, means at least half of the items. As used herein, any structure or layer that is described as being “made of” or “composed of” a substance should be understood (i) in some embodiments, to contain that substance as the primary component or (ii) in some embodiments, to contain that substance as the major component.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

It will be understood that when an element is referred to as being “directly connected” or “directly coupled” to another element, there are no intervening elements present. As used herein, “generally connected” means connected by an electrical path that may contain arbitrary intervening elements, including intervening elements the presence of which qualitatively changes the behavior of the circuit. As used herein, “connected” means (i) “directly connected” or (ii) connected with intervening elements, the intervening elements being ones (e.g., low-value resistors or inductors, or short sections of transmission line) that do not qualitatively affect the behavior of the circuit.

Although limited embodiments of a resonator constructed with one or more Van der Waals materials have been specifically described and illustrated herein, many modifications and variations will be apparent to those skilled in the art. Accordingly, it is to be understood that a resonator constructed with one or more Van der Waals materials employed according to principles of this disclosure may be embodied other than as specifically described herein. Features of some embodiments are also defined in the following claims, and equivalents thereof.

What is claimed is:

1. A system, comprising:
a resonator, comprising:
a capacitor; and
an inductor,
the capacitor comprising:
a first conductive layer;
an insulating layer, on the first conductive layer; and
a second conductive layer on the insulating layer,
the first conductive layer being composed of one or more layers of a first van der Waals material,
the insulating layer being composed of one or more layers of a second van der Waals material, and
the second conductive layer being composed of one or more layers of a third van der Waals material.

2. The system of claim 1, wherein the capacitor further comprises:
an insulating lower layer, under the first conductive layer; and
an insulating upper layer, on the second conductive layer, wherein:
the insulating lower layer is composed of one or more layers of a first van der Waals material, and
the insulating upper layer is composed of one or more layers of a first van der Waals material.

3. The system of claim 1, wherein the capacitor further comprises:
a first layer of graphene, between the first conductive layer and the insulating layer; and
a second layer of graphene, between the insulating layer and the second conductive layer.

4. The system of claim 1, wherein the first conductive layer is a superconducting layer and the second conductive layer is a superconducting layer.

5. The system of claim 1, wherein the first van der Waals material is a material selected from the group consisting of NbSe₂, MoTe₂, WTe₂, TaS₂, BSCCO, graphene, and combinations thereof.

6. The of claim 1, wherein the third van der Waals material is the same material as the first van der Waals material.

7. The system of claim 1, wherein the second van der Waals material is a material selected from the group consisting of BN, WSe₂, MoS₂, MoSe₂, WS₂, MoTe₂, PtS₂, PtSe₂, PtTe₂, HfS₂, HfSe₂, ReS₂, ReSe₂, SnS₃, SnSe₂, ZrS₂, ZrSe₂, silicene, germanene, black phosphorus, and combinations thereof.

8. The system of claim 1, wherein the inductor has an inductance that is primarily due to geometric inductance.

9. The system of claim 1, wherein the inductor has an inductance that is primarily due to kinetic inductance.

10. The system of claim 1, wherein the inductor has an inductance that is primarily due to a Josephson inductance.

11. The system of claim 10, wherein the Josephson inductance is an inductance of a Josephson junction, the Josephson junction comprising:
a first conductive layer, contiguous with the first conductive layer of the capacitor;
an insulating layer, contiguous with the insulating layer of the capacitor; and
a second conductive layer, contiguous with the second conductive layer of the capacitor.

12. The system of claim 11, wherein the insulating layer of the Josephson junction is thinner than the insulating layer of the capacitor.

13. The system of claim 10, wherein the Josephson inductance is an inductance of a Josephson junction, the Josephson junction being formed between the first conductive layer and the second conductive layer.

14. The system of claim 13, wherein an overlap of a wavefunction of electrons of the first conductive layer with a wavefunction of electrons of the second conductive layer results in the formation of the Josephson junction.

15. The system of claim 1, further comprising:
a first electrode, in contact with the first conductive layer, and
a second electrode, in contact with the second conductive layer.

16. The system of claim 15, wherein the first electrode is composed of a superconducting material.

17. The system of claim 16, wherein the first electrode is composed of a material selected from the group consisting of aluminum, niobium, niobium nitride, niobium titanium nitride, titanium nitride, and molybdenum rhenium.

18. The system of claim 1, further comprising a qubit, wherein:
the capacitor is a first capacitor, and
the qubit is capacitively coupled to the first capacitor.

19. The system of claim 18, wherein:
the qubit comprises a second capacitor; and
the second capacitor comprises:
a first conductive layer;
an insulating layer, on the first conductive layer; and
a second conductive layer on the insulating layer.

20. The system of claim 19, wherein the qubit is capacitively coupled to the first capacitor as a result of an overlap between the first conductive layer of the second capacitor and the second conductive layer of the first capacitor.
